(19) United States
(12) Patent Application Publication
(10) Pub. No.: US 2010/0224849 A1
(43) Pub. Date: Sep. 9, 2010

(54) Oxide diode, method of manufacturing the same, and electronic device and resistive memory device including the same

(75) Inventor: Bo-soo Kang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,826

(22) Filed: Oct. 29, 2009

(30) Foreign Application Priority Data
Mar. 9, 2009 (KR) 10-2009-0019861

(51) Int. Cl. H01L 45/00; H01L 29/12; H01L 21/329

(52) U.S. Cl. 257/4; 257/43; 438/104; 257/E29.068; 257/E21.352; 257/E45.002

(57) ABSTRACT

Provided are an oxide diode, a method of fabricating the oxide diode, and an electronic device including the oxide diode. The oxide diode may include an n-type oxide layer treated with plasma, and a p-type oxide layer on the n-type oxide layer. The plasma may include nitrogen.

### CROSS-REFERENCE TO RELATED APPLICATIONS

This application claims priority under 35 USC §119 to Korean Patent Application No. 10-2009-0019861, filed on Mar. 9, 2009, in the Korean Intellectual Property Office (KIPO), the entire contents of which are incorporated herein by reference.

### BACKGROUND

1. Field

Example embodiments relate to an oxide diode, method of manufacturing the same and an electronic device including the oxide diode.

2. Description of the Related Art

Oxide semiconductors may be fabricated at a relatively low temperature and have higher mobility, and accordingly, research for applying oxide semiconductors to various electronic devices is being conducted.

However, adjusting the doping concentration of oxide materials may be difficult when compared with silicon, the oxide materials may be incorrectly bonded to a selected material layer (for example, other oxide materials), and oxide semiconductors may not be compatible with a mass production line of silicon based devices. Accordingly, developing electronic devices employing oxide semiconductors may be difficult.

### SUMMARY

Example embodiments include an oxide diode having improved performance and a method of fabricating the oxide diode. Example embodiments also include an electronic device including the oxide diode.

Additional aspects will be set forth in part in the description which follows and, in part, will be apparent from the description, or may be learned by practice of example embodiments.

According to example embodiments, a diode may include an n-type oxide layer including an upper surface treated with plasma and a p-type oxide layer on the n-type oxide layer.

The n-type oxide layer may include one selected from the group consisting of InZn oxide, InSn oxide, Zn oxide, Sn oxide, Ti oxide, and compounds thereof. The p-type oxide layer may include one selected from the group consisting of Cu oxide, Ni oxide, CuAl oxide, ZnRh oxide, SrCu oxide, and compounds thereof. The plasma may include nitrogen. The plasma may include N₂O plasma or N₂ plasma.

According to example embodiments, a method of fabricating a diode may include forming an n-type oxide layer; treating an upper surface of the n-type oxide layer with plasma; and forming a p-type oxide layer on the n-type oxide layer.

The n-type oxide layer may include one selected from the group consisting of InZn oxide, InSn oxide, Zn oxide, Sn oxide, Ti oxide, and compounds thereof. The p-type oxide layer may include one selected from the group consisting of Cu oxide, Ni oxide, CuAl oxide, ZnRh oxide, SrCu oxide, and compounds thereof. The plasma may include nitrogen. The plasma may include N₂O plasma or N₂ plasma.

According to example embodiments, an electronic device may include the above described diode of example embodiments. The electronic device may include a memory device including a data storage unit connected to the diode.

According to example embodiments, a resistive memory device may include at least one first electrode, at least one second electrode on the at least one first electrode and separated from the at least one first electrode, and a first stacked structure including a first resistance changing layer and a first switching device between the at least one first and second electrodes, and the first switching device may include a resistive memory device, e.g., a diode.

The n-type oxide layer of the diode may include one selected from the group consisting of InZn oxide, InSn oxide, Zn oxide, Sn oxide, Ti oxide, and compounds thereof. The p-type oxide layer of the diode may include one selected from the group consisting of Cu oxide, Ni oxide, CuAl oxide, ZnRh oxide, SrCu oxide, and compounds thereof. The plasma may include nitrogen.

The at least one first electrode may be a plurality of first electrodes arranged in parallel as wires, the at least one second electrode may be a plurality of second electrodes arranged in parallel to cross the plurality of first electrodes, and the stacked structure may be at an intersection point of each of the plurality of first and second electrodes.

The resistive memory device may further include at least one third electrode under the at least one first electrode and separate from the at least one first electrode, and a second stacked structure including a second resistance changing layer and a second switching device between the at least one first and third electrodes.

The second switching device may include a diode. Rectifying directions of the switching device and the second switching device may be opposite to each other or may be the same as each other. The first switching device, the first resistance changing layer, and the at least one second electrode may be on the at least one first electrode, and the second switching device, the second resistance changing layer, and the at least one third electrode may be under the at least one first electrode.

The at least one first electrode may be a plurality of first electrodes arranged in parallel as wires, the at least one third electrode may be a plurality of third electrodes arranged in parallel and crossing the plurality of first electrodes, and the second stacked structure may be at an intersection point of each of the plurality of first and third electrodes. The resistive memory device may include a multi-crossing memory device having a cell structure of 1 diode (1D)-1 resistor (1R).

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of an oxide diode according to example embodiments;

FIGS. 2A through 2C are cross-sectional views illustrating a method of fabricating the oxide diode illustrated in FIG. 1, according to example embodiments;

FIG. 3 is a graph showing voltage-current characteristics of the oxide diode illustrated in FIG. 1;

FIG. 4 is a graph showing voltage-current characteristics of an oxide diode according to a comparative example;

FIG. 5 is a graph showing voltage-current characteristics of an oxide diode according to example embodiments;

FIG. 6 is a graph showing voltage-current characteristics of an oxide diode according to another comparative example;

FIG. 7 is a graph showing a secondary ion mass spectrometry (SIMS) analysis result of an oxide diode according to example embodiments;

FIG. 8 is a graph showing a SIMS analysis result of an oxide diode according to a comparative example;

FIG. 9 is a graph showing voltage-current characteristics of an oxide diode according to example embodiments;

FIG. 10 is a graph showing voltage-current characteristics of an oxide diode according to another comparative example;

FIG. 11 is a perspective view of a resistive memory device according to example embodiments;

FIG. 12 is a circuit diagram of the resistive memory device illustrated in FIG. 11; and

FIG. 13 is a plan view of a resistive memory device according to example embodiments.

### DETAILED DESCRIPTION

Various example embodiments will now be described more fully with reference to the accompanying drawings in which some example embodiments are shown. Detailed illustrative example embodiments are disclosed herein. However, specific structural and functional details disclosed herein are merely representative for purposes of describing example embodiments. In this regard, example embodiments may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it may be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. In the drawings, the thicknesses of layers and regions are exaggerated for clarity. Like reference numerals in the drawings denote like elements.

Reference will now be made in detail to example embodiments, which are illustrated in the accompanying drawings, wherein like reference numerals refer to the like elements throughout. In this regard, example embodiments may have different forms and should not be construed as being limited to the descriptions set forth herein. Accordingly, example embodiments are merely described below, by referring to the figures, to explain aspects of the present description.

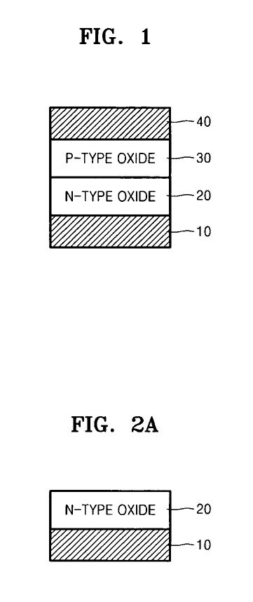

FIG. 1 illustrates an oxide diode according to example embodiments. Referring to FIG. 1, the oxide diode according to example embodiments may include an n-type oxide layer 20, a p-type oxide layer 30, and an upper electrode 40 sequentially formed on a lower electrode 10 in the stated order. An upper surface of the n-type oxide layer 20, e.g., a surface of the n-type oxide layer 20 facing the p-type oxide layer 30, may be treated with plasma.

The n-type oxide layer 20 may include one selected from the group consisting of InZn oxide, InSn oxide, Zn oxide, Sn oxide, Ti oxide, and compounds thereof. When the n-type oxide layer 20 includes the InZn oxide, e.g., InZnOx (0<x≦2.5), Zn²⁺, which either exists outside a lattice or is not combined with O due to Zn interstitial which are generated naturally and O vacancy, may function as an acceptor and thus the InZnOx may become an n-type semiconductor. Similarly, InSn oxide (InSnO), Zn oxide (ZnO), Sn oxide (SnO₂), and Ti oxide (TiO₂) may become n-type semiconductors due to the O vacancies.

The p-type oxide layer 30 may include one selected from the group consisting of Cu oxide, Ni oxide, CuAl oxide, ZnRh oxide, SrCu oxide, and compounds thereof. The Cu oxide may be CuOx (x≧1), and in the CuOx, O²⁻, which is not combined with Cu due to spontaneous Cu deficiency, may function as a donor, and thus the CuOx may become a p-type semiconductor. Cu₂O, which is another example of the Cu oxide, may form the p-type semiconductor. Similarly, Ni oxide (NiO), CuAl oxide (CuAlO₂), ZnRh oxide (ZnRh₂O₄), and SrCu oxide (SrCu₂O₂) may form the p-type semiconductor due to O²⁻ which functions as the donor.

Because the upper surface of the n-type oxide layer 20 is treated with plasma, a junction property between the n-type oxide layer 20 and the p-type oxide layer 30 may be improved. In more detail, excessive O vacancies may exist in the upper surface of the n-type oxide layer 20, and thus, electrical conductivity of the upper surface of the n-type oxide layer 20 may be increased to an undesired level. The plasma treatment may reduce the electrical conductivity to a normal level. Therefore, the n-type oxide layer 20, the upper surface of which is treated with plasma, may make an improved diode junction with the p-type oxide layer 30. If the upper surface of the n-type oxide layer 20 is not treated with plasma, the n-type oxide layer 20 may not make an improved diode junction with the p-type oxide layer 30, but may be tunnel-joined with the p-type oxide layer 30. Thus, the junction between the n-type oxide layer 20 and the p-type oxide layer 30 may be tunneled easily when a reverse voltage is applied. For example, when the upper surface of the n-type oxide layer 20 is not treated with plasma, a depletion region formed at the junction between the n-type oxide layer 20 and the p-type oxide layer 30 is very thin. In these circumstances, the combination of the n-type oxide layer 20 and the p-type oxide layer 30 may not function as a diode. However, when the upper surface of the n-type oxide layer 20 is treated with plasma as in example embodiments, the n-type oxide layer 20 may make an improved diode-junction with the p-type oxide layer 30.

The plasma used to treat the upper surface of the n-type oxide layer 20 may include nitrogen, for example, N₂O plasma or N₂ plasma. When the upper surface of the n-type oxide layer 20 is treated with the plasma including nitrogen, nitrogen may be doped into the upper surface of the n-type oxide layer 20. The doping of nitrogen into the n-type oxide layer 20 including InZn oxide, InSn oxide, Zn oxide, Sn oxide, or Ti oxide may have the same effect as that of p-type doping. Therefore, the electrical conductivity of the upper surface of the n-type oxide layer 20, which is increased by the excessive O vacancies, may be reduced to a normal level according to the plasma treatment. In addition, when N₂O plasma is used to process the upper surface of the n-type oxide layer 20, the upper surface of the n-type oxide layer 20 may be oxidized, and the oxidation may also reduce the amount of O vacancies.

On the other hand, each of the lower electrode 10 and the upper electrode 40 may include a general electrode material, for example, one selected from the group consisting of Pt, Cu, Al, Mo, W, Au, Pd, Ir, Ag, Ni, and compounds thereof, and may be formed in a single-layered structure or a multi-layered structure. Materials and structures of the lower and upper electrodes 10 and 40 may be the same as each other, or may be different from each other.

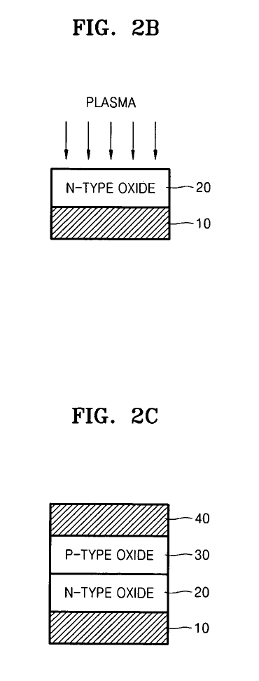

FIGS. 2A through 2C illustrate a method of fabricating the oxide diode illustrated in FIG. 1, according to example embodiments. Referring to FIG. 2A, the lower electrode 10 may be formed, and the n-type oxide layer 20 may be formed on the lower electrode 10. The lower electrode 10 may be formed by using a physical vapor deposition (PVD) method, for example, a sputtering method; however, the lower electrode 10 may be formed by using other deposition methods, e.g., a chemical vapor deposition (CVD) method. The lower electrode 10 may be formed of at least one of a plurality of general electrode materials, for example, Pt, Cu, Al, Mo, W, Au, Pd, Ir, Ag, and Ni, and may be formed in a single-layered structure or a multi-layered structure.

The n-type oxide layer 20 may be formed of one selected from the group consisting of InZn oxide, InSn oxide, Zn oxide, Sn oxide, Ti oxide, and compounds thereof. If the n-type oxide layer 20 includes an InZnOx (0<x≦2.5) composition, the n-type oxide layer 20 may be formed using a sputtering method using InZn oxide as a target. In the above sputtering method, a radio frequency (RF) power of about 300 W may be used. Argon (Ar) and oxygen (O₂) gases may flow into a deposition chamber at flow rates of about 100 sccm and 10 sccm, respectively, to maintain a pressure in the deposition chamber of about 1 mTorr. The above deposition conditions are merely an example however, and the RF power, the kinds of gases and flow rates thereof, and the pressure in the deposition chamber may be modified. Excessive O vacancies may exist on the upper surface of the n-type oxide layer 20.

Referring to FIG. 2B, the upper surface of the n-type oxide layer 20 may be treated with plasma. The plasma may include nitrogen, for example, N₂O plasma or N₂ plasma. When the n-type oxide layer 20 is heated to a temperature of about 150° C., the upper surface of the n-type oxide layer 20 may be treated with the N₂O plasma for about 5 minutes by using a relatively low source power of about 50 W or less. When the upper surface of the n-type oxide layer 20 is treated with plasma by using the relatively low source power, damage to the upper surface of the n-type oxide layer 20 may be prevented or reduced. The above heating temperature of the n-type oxide layer 20, the magnitude of the source power, and the plasma treatment time are merely examples, however. The source power may be determined to be about 2000 W or less, and the plasma treatment time may be in a range of several minutes to tens of minutes. Further, the n-type oxide layer 20 may heated to a temperature in a range of about tens to about hundreds of ° C.

Through the above plasma treatment, the nitrogen may be doped into the upper surface of the n-type oxide layer 20, and in some cases, the upper surface of the n-type oxide layer 20 may be oxidized. Therefore, the electrical conductivity of the upper surface of the n-type oxide layer 20, which is increased by the excessive O vacancies, may be reduced to a normal level.

Referring to FIG. 2C, the p-type oxide layer 30 may be formed on the n-type oxide layer 20. The p-type oxide layer 30 may be formed of one selected from the group consisting of copper (Cu) oxide, nickel (Ni) oxide, copper aluminum (CuAl) oxide, zinc rhodium (ZnRh) oxide, strontium copper (SrCu) oxide, and compounds thereof. For example, if the p-type oxide layer 30 includes a CuOx (x≧1) composition, the p-type oxide layer 30 may be formed by using a sputtering method using Cu as a target. In the above sputtering process, an RF power of about 250 W may be used, and the pressure of the deposition chamber may be maintained at about 5 mTorr while Ar and O₂ gases flow into the deposition chamber at flow rates of about 50 sccm and about 5 sccm, respectively.

The above deposition conditions are merely an example however, and the RF power, the kinds of gases and flow rates thereof, and the pressure in the deposition chamber may be modified variously. The upper electrode 40 may be formed on the p-type oxide layer 30. The upper electrode 40 may be formed of at least one of a plurality of general electrode materials, for example, platinum (Pt), copper (Cu), aluminum (Al), molybdenum (Mo), tungsten (W), gold (Au), palladium (Pd), iridium (Ir), silver (Ag), and nickel (Ni), and may be formed in a single-layered structure or in a multi-layered structure. The material forming the upper electrode 40 and the structure of the upper electrode 40 may be the same as or different from those of the lower electrode 10.

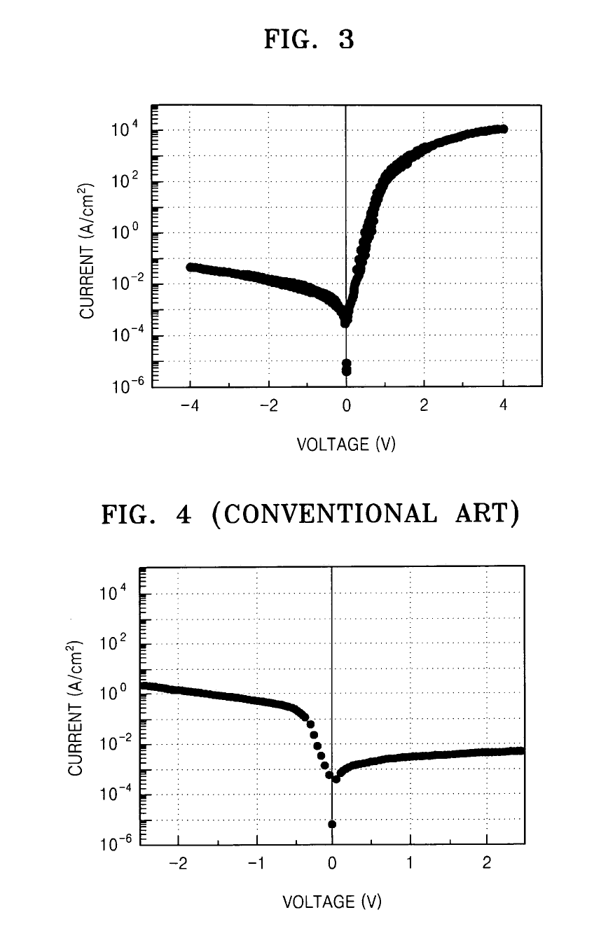

FIG. 3 is a graph showing voltage-current characteristics of the oxide diode illustrated in FIG. 1. In example embodiments, a Pt layer, an InZnOx layer, a CuOx layer, and a Pt layer are respectively used as the lower electrode 10, the n-type oxide layer 20, the p-type oxide layer 30, and the upper electrode 40. The upper surface of the InZnOx layer, e.g., a surface bonded with the CuOx layer, is treated with N₂O plasma. Hereinafter, the oxide diode used to obtain the results shown in FIG. 3 will be referred to as ‘first sample diode’.

Referring to FIG. 3, improved rectifying characteristics, e.g., a forward current density of about 104 A/cm² or greater and a ratio between forward current/backward current of about 106 or greater, may be obtained.

FIG. 4 shows voltage-current characteristics of an oxide diode according to a comparative example. The oxide diode used to obtain the results shown in FIG. 4 is a first comparative sample, which has the same structure as the first sample diode except for that an upper surface of the n-type oxide layer (InZnOx layer) is not treated with plasma.

Referring to FIG. 4, a forward current density is relatively low, and a backward current density is higher than the forward current density. For example, the electrical current rarely flows in the forward direction, and more current flows in the undesired direction (backward direction). The above results show that the desired rectifying characteristic is not obtained because of undesirable junction properties between the n-type oxide layer (InZnOx layer) and the p-type oxide layer (CuOx layer) when the upper surface of the n-type oxide layer (InZnOx layer) is not treated with plasma.

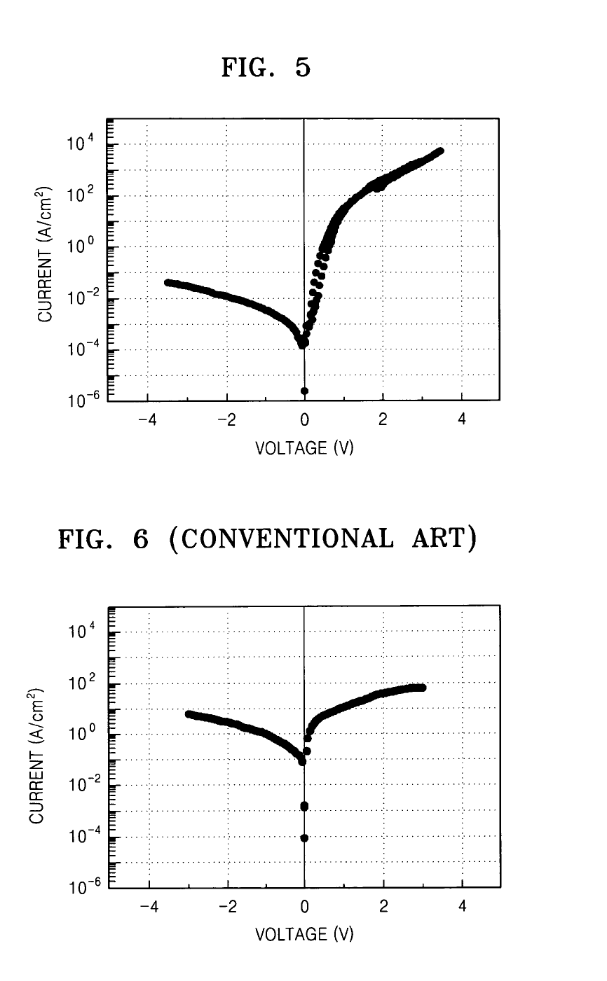

FIG. 5 is a graph showing voltage-current characteristics of an oxide diode according to example embodiments. The diode used to obtain the results shown in FIG. 5 has the same structure as the first sample diode except that a Cu layer is used as the lower electrode 10. For example, the oxide diode used to obtain the results of FIG. 5 (hereinafter, referred to as a second sample diode) has a structure of Cu/InZnOx/CuOx/Pt layers. An upper surface of the n-type oxide layer (InZnOx layer) in the second sample diode is treated with N₂O plasma similar to the first sample diode.

Referring to FIG. 5, improved rectifying characteristics are shown similar to the results of FIG. 3. FIG. 6 shows voltage-current characteristics of an oxide diode according to another comparative example. The oxide diode used to obtain the results shown in FIG. 6 is a second comparative sample, which has the same structure as the second sample diode except that the upper surface of the n-type oxide layer (InZnOx layer) is not treated with plasma. Referring to FIG. 6, the forward current density is relatively low at about 102 A/cm², and a ratio between the forward current/backward current is relatively low at about 102.

When comparing the graphs shown in FIGS. 3 and 4, and FIGS. 5 and 6 with each other, the rectifying characteristics of the oxide diode may be improved when the upper surface of the n-type oxide layer is treated with plasma.

When the n-type oxide layer is formed on the p-type oxide layer, for example, when the InZnOx layer is formed on the CuOx layer, a diode junction may be formed with the CuOx layer and the InZnOx layer without the plasma treatment, and accordingly, rectifying characteristics may be observed. However, as identified in FIGS. 4 and 6, when the p-type oxide layer is formed on the n-type oxide layer, the n-type oxide layer and the p-type oxide layer may not form a normal diode junction. Then, the upper surface of the n-type oxide layer may be treated with plasma according to example embodiments.

Additionally, the difference between the graphs shown in FIGS. 4 and 6 may be caused by a difference between materials forming the lower electrodes. The first comparative sample uses the Pt layer as the lower electrode, and the second comparative sample uses the Cu layer as the lower electrode. Because the Pt layer has a work function that is greater than that of the Cu layer, a Schottky junction may be formed between the n-type oxide layer (InZnOx layer) and the Pt layer. The Schottky junction may be extinguished as time proceeds.

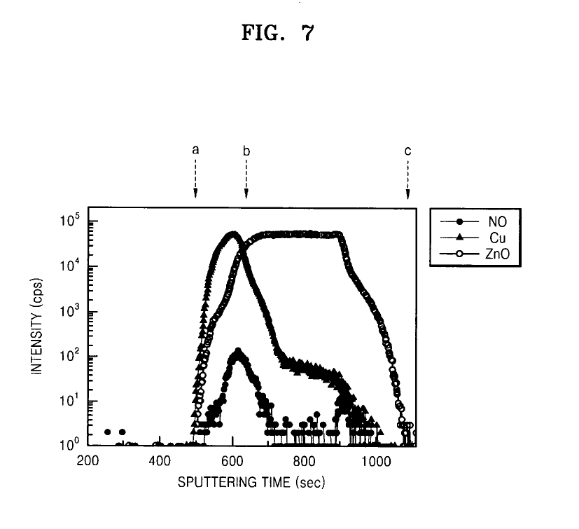

FIG. 7 is a graph showing a secondary ion mass spectrometry (SIMS) analysis result of the structure of an oxide diode including an InZnOx layer and a CuOx layer according to example embodiments. For example, FIG. 7 shows a result of analyzing changes in composition according to depth while sputtering the structure of InZnOx/CuOx. The upper surface of the InZnOx layer is treated with N₂O plasma for about 4 minutes. In FIG. 7, point (a) corresponds to the upper surface of the CuOx layer, point (b) corresponds to the interface between the CuOx layer and the InZnOx layer, and point (c) corresponds to the lower surface of the InZnOx layer. Referring to FIG. 7, a large amount of nitrogen (N) exists in the InZnOx layer which is adjacent to the CuOx layer, e.g., around the point b.

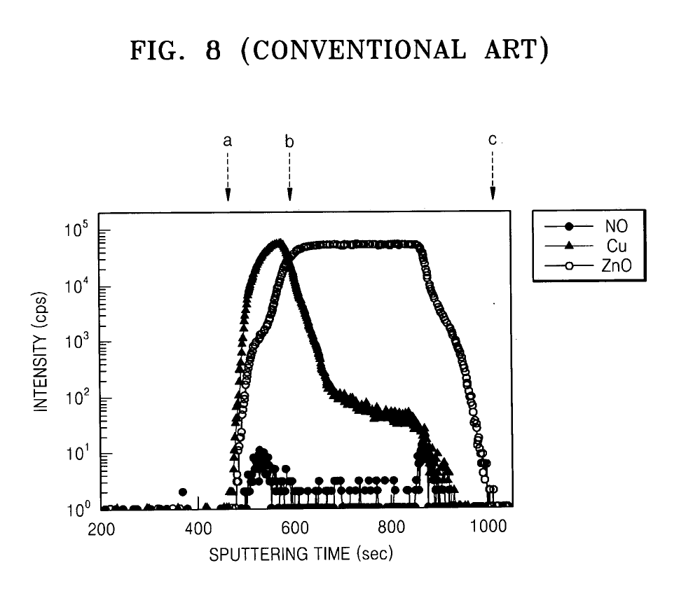

FIG. 8 shows a SIMS analysis result of an oxide diode structure including an InZnOx layer and a CuOx layer according to the comparative example. The InZnOx layer is not treated with plasma. In FIG. 8, points a, b, and c are the same as those of FIG. 7. Referring to FIG. 8, only a small amount of nitrogen (N) exists in the InZnOx layer. From the results of FIGS. 7 and 8, the nitrogen (N) is doped in the upper surface of the InZnOx layer due to the N₂O plasma treatment in example embodiments.

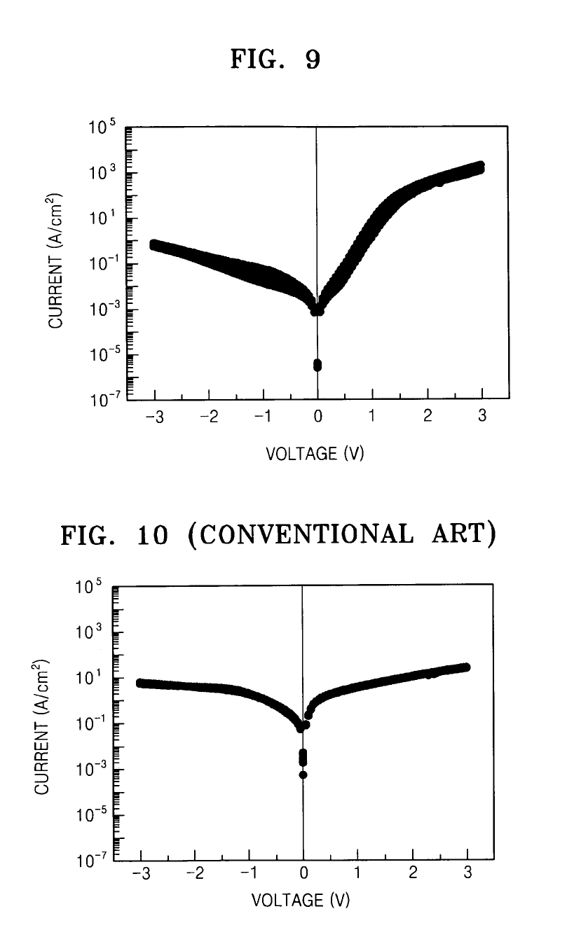

FIG. 9 is a graph showing a voltage-current characteristic of an oxide diode according to example embodiments. The oxide diode used to obtain the result shown in FIG. 9 (hereinafter referred to as a third sample diode) has a stacked structure of Cu/InZnOx/CuOx/Cu layers, and the InZnOx layer (n-type oxide layer) is treated with N₂ plasma. Referring to FIG. 9, improved rectifying characteristics are shown similarly to the results shown in FIG. 3.

FIG. 10 is a graph showing a voltage-current characteristic of an oxide diode according to another comparative example. The oxide diode used to obtain the result of FIG. 10 is a third comparative sample having the same stacked structure as the third sample diode except that the InZnOx layer (n-type oxide layer) is not treated with plasma. Referring to FIG. 10, the forward current density is relatively low about 10 A/cm², and a ratio between the forward current/backward current is about 1. From the results shown in FIGS. 9 and 10, the rectifying characteristics of the oxide diode may be improved due to the N₂ plasma treatment.

The oxide diode according to example embodiments may be applied in various multi-functional electronic devices. For example, the oxide diode of example embodiments may be applied as a switching device in a memory device. The memory device may include a data storage unit and a switching device connecting to the data storage unit. The data storage unit may include a material layer, e.g., a resistance changing layer, a ferroelectric layer, a ferromagnetic layer, or a phase changing layer, which may store bit data. The switching device may control access of signals to the data storage unit. The oxide diode of example embodiments may be used as the switching device.

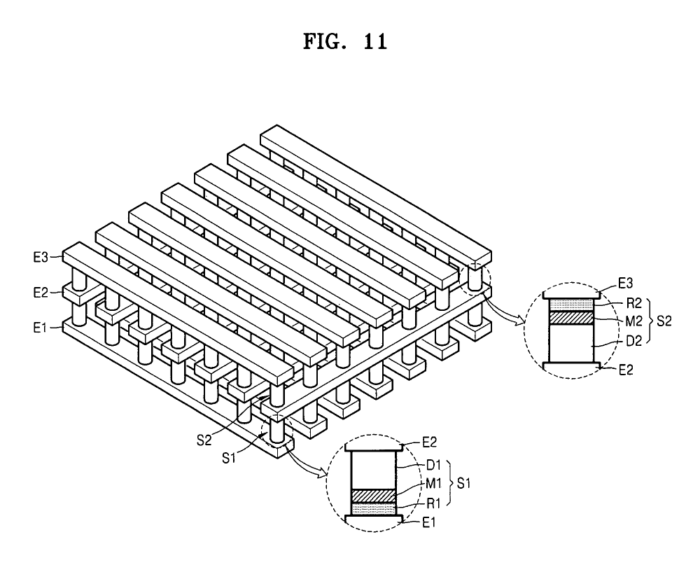

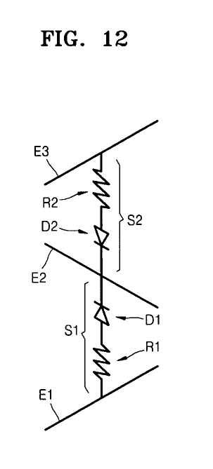

FIG. 11 is a perspective view a resistive memory device according to example embodiments. The resistive memory device illustrated in FIG. 11 may include an oxide diode according to example embodiments, and may be a multi-layer cross point resistive memory device having a 1 diode (1D)-1 resistor (1R) cell structure.

Referring to FIG. 11, the resistive memory device according to example embodiments may include a plurality of first wires E1 which are arranged in parallel with each other and extend in a first direction, and a plurality of second wires E2 which are formed to extend in a direction crossing the first direction in which the first wires E1 extend. In addition, a first stacked structure S1 may be formed at each point where the first and second wires E1 and E2 cross each other. The first stacked structure S1 may include a first resistance changing layer R1, a first intermediate electrode M1, and a first diode D1 which are stacked sequentially on the first wire E1. Locations of the first resistance changing layer R1 and the first diode D1 may be changed.

A plurality of third wires E3 may be formed to be separated a selected distance from upper surfaces of the second wires E2. The third wires E3 may be separated by constant intervals from each other, and may cross the second wires E2. A second stacked structure S2 may be formed at each point where the second and third wires E2 and E3 cross each other. The second stacked structure S2 may include a second intermediate electrode M2 and a second resistance changing layer R2 sequentially stacked on a second diode D2. At least one of the first and second diodes D1 and D2, for example, the second diode D2, may have the same structure as the oxide diode illustrated in FIG. 1.

FIG. 12 is a circuit diagram of the first wire E1, the first stacked structure S1, the second wire E2, the second stacked structure S2, and the third wire E3, according to example embodiments. Referring to FIG. 12, rectifying directions of the first and second diodes D1 and D2 may be opposite to each other. In example embodiments, one of the first and second diodes D1 and D2 may have the same structure as that of the oxide diode illustrated in FIG. 1. For example, the first diode D1 may include an n-type first semiconductor layer on a p-type first semiconductor layer, and the second diode D2 may include a p-type second semiconductor layer on an n-type second semiconductor layer. In example embodiments, the second diode D2 may have the same structure as that of the oxide diode illustrated in FIG. 1. For example, the second diode D2 may be an oxide diode including a p-type oxide layer on an n-type oxide layer, and the upper surface of the n-type oxide layer (e.g., the surface bonded with the p-type oxide layer) may be treated with plasma.

Materials forming the n-type oxide layer and the p-type oxide layer and conditions for plasma treatment may be the same as those described with reference to FIGS. 1 and 2A-2C. Therefore, the rectifying characteristics of the second diode D2 may be similar to the rectifying characteristics illustrated in the graphs of FIGS. 3 and 5. On the other hand, the first diode D1 may be an oxide diode including an n-type oxide layer on a p-type oxide layer, and the upper surface of the p-type oxide layer may not be treated with plasma.

In the circuit diagram of FIG. 12, the first and second stacked structures S1 and S2 may be symmetric with each other with reference to the second wire E2. The rectifying directions of the first and second diodes D1 and D2 may be opposite to each other. In this structure, information may be recorded in the first and second resistance changing layers R1 and R2 simultaneously by using the second wires E2 as common bit lines. However, the information may be recorded in one of the first and second resistance changing layers R1 and R2 with one operation. For example, the first and second resistance changing layers R1 and R2 may be programmed simultaneously or independently in the structure illustrated in FIG. 12.

In FIG. 12, the rectifying directions of the first and second diodes D1 and D2 are opposite to each other; however, example embodiments are not limited to the above example. In other example embodiments, the rectifying directions of the first and second diodes D1 and D2 may be different, locations of the first resistance changing layer R1 and the first diode D1 may be changed with each other, and locations of the second resistance changing layer R2 and the second diode D2 may be changed with each other. Therefore, both of the first and second diodes D1 and D2 may have the same structure as that of the oxide diode illustrated in FIG. 1.

Although not shown in the drawings, the resistive memory device illustrated in FIG. 11 may further include a stack structure having the same stack structure in which the first stacked structures S1 and the second wire E2 are stacked on the third wire E3.

Otherwise, the resistive memory device illustrated in FIG. 11 may further include at least one set of stack structures having the same stack structure in which the first stacked structure S1, the second wire E2, and the second stacked structure S2 are stacked on the third wire E3. Otherwise, the resistive memory device illustrated in FIG. 11 may further include at least one set of stack structures having the same stack structure in which the first stacked structure S1, the second wire E2, the second stacked structure S2, the third wire E3, the first stacked structure S1 and the second wire E2 are stacked on the third wire E3.

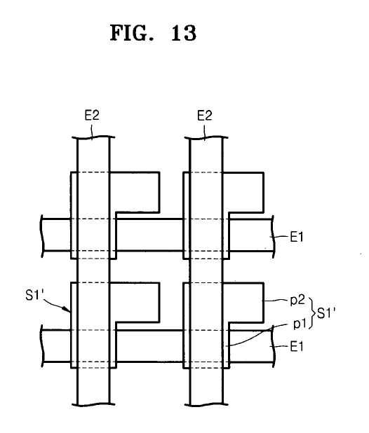

In FIG. 11, the first and second stacked structures S1 and S2 may be formed as cylinders; however, shapes of the first and second stacked structures S1 and S2 may be modified variously, for example, may be formed as square pillars or pillars that increase in width in the downward direction. For example, the first and second stacked structures S1 and S2 may have asymmetric shapes, which extend beyond the crossing points between the first and second wires E1 and E2 and the second and third wires E2 and E3. An example of a first stacked structure S1′ having an asymmetric shape is illustrated in FIG. 13.

FIG. 13 is a plan view of a resistive memory device according to example embodiments. Referring to FIG. 13, the first stacked structure S1′ may include a first portion p1 which is formed at the crossing point between the first and second wires E1 and E2, and a second portion p2 which contacts the first portion p1 and extends beyond the crossing point. For example, the first stacked structure S1′ has an asymmetric shape which extends outside the crossing point between the first and second wires E1 and E2. The first stacked structure S1′ may have a stacked structure which is similar to that of the first stacked structure S1 illustrated in FIG. 11, and a shape (top view) of the first diode in the first stacked structure S1′ and a shape (top view) of the first resistance changing layer R1 may be different from each other.

For example, the first switching device (first diode) may be formed to have an area which corresponds to the first portion p1 and the second portion p2, and the first resistance changing layer may be formed to have an area corresponding to the first portion p1. However, the first resistance changing layer may be formed on an entire lower surface of the first intermediate electrode. In example embodiments, the portion of the first resistance changing layer at the crossing point of the first wire E1 and the first intermediate electrode may be effective, and remaining regions of the first resistance changing layer outside the crossing point may not be effective. A contact electrode layer, which covers an entire upper surface of the first diode, may be further disposed between the first diode and the second wire E2. As illustrated in FIG. 13, when the first diode is formed to be large, the forward current of the first diode may increase and the switching property of the first diode may be improved. The second stacked structure S2 illustrated in FIG. 11 may be modified to have a similar structure to that of the first stacked structure S1′.

In addition, the resistance changing layers R1 and R2 illustrated in FIGS. 11 through 13 may be formed of a variable resistive material, for example, a transition metal oxide (TMO). In more detail, the resistance changing layers R1 and R2 may be formed of at least one selected from the group consisting of Ni oxide, Cu oxide, Ti oxide, Co oxide, Hf oxide, Zr oxide, Zn oxide, W oxide, Nb oxide, TiNi oxide, LiNi oxide, Al oxide, InZn oxide, V oxide, SrZr oxide, SrTi oxide, Cr oxide, Fe oxide, Ta oxide, and compounds thereof. The variable resistive materials may be reversibly converted from a high-resistive state to a low-resistive state or from a low-resistive state to a high-resistive state.

Therefore, the resistive memory device according to example embodiments may be a rewritable memory. However, example embodiments are not limited to the above example. If the resistance changing layers R1 and R2 include an element which irreversibly changes from the high-resistive state to the low-resistive state, the memory cell, which has been programmed, may not be returned to the original state. Therefore, the memory device may be a one-time programmable (OTP) memory. An example of the irreversible changing element may be an antifuse, and the antifuse may be formed of a dielectric material, for example, a silicon oxide or a silicon nitride.

It should be understood that example embodiments described therein should be considered in a descriptive sense only and not for purposes of limitation. Descriptions of features or aspects within each example embodiment should typically be considered as available for other similar features or aspects in other example embodiments. For example, one of ordinary skill in the art may recognize that the oxide diode according to example embodiments may be applied to various electronic devices besides memory devices. In addition, one of ordinary skill in the art may know that an n-type oxide layer which is treated with plasma may be used to fabricate devices other than an oxide diode.

What is claimed is:

1. A diode comprising:
an n-type oxide layer including an upper surface treated with plasma; and
a p-type oxide layer on the n-type oxide layer.

2. The diode of claim 1, wherein the n-type oxide layer includes one selected from the group consisting of InZn oxide, InSn oxide, Zn oxide, Sn oxide, Ti oxide, and compounds thereof.

3. The diode of claim 1, wherein the p-type oxide layer includes one selected from the group consisting of Cu oxide, Ni oxide, CuAl oxide, ZnRh oxide, SrCu oxide, and compounds thereof.

4. The diode of claim 1, wherein the plasma includes nitrogen.

5. The diode of claim 4, wherein the plasma includes N₂O plasma or N₂ plasma.

6. A method of fabricating a diode, the method comprising:
forming an n-type oxide layer;
treating an upper surface of the n-type oxide layer with plasma; and
forming a p-type oxide layer on the n-type oxide layer.

7. The method of claim 6, wherein the n-type oxide layer includes one selected from the group consisting of InZn oxide, InSn oxide, Zn oxide, Sn oxide, Ti oxide, and compounds thereof.

8. The method of claim 6, wherein the p-type oxide layer includes one selected from the group consisting of Cu oxide, Ni oxide, CuAl oxide, ZnRh oxide, SrCu oxide, and compounds thereof.

9. The method of claim 6, wherein the plasma includes nitrogen.

10. The method of claim 9, wherein the plasma includes N₂O plasma or N₂ plasma.

11. An electronic device comprising the diode of claim 1.

12. The electronic device of claim 11, further comprising:
a memory device including a data storage unit connected to the diode.

13. A resistive memory device comprising:
at least one first electrode;
at least one second electrode above the at least one first electrode and separate from the at least one first electrode; and
a first stacked structure including a first resistance changing layer and a first switching device between the at least one first and second electrodes,
wherein the first switching device includes a diode including an n-type oxide layer having an upper surface treated with plasma, and a p-type oxide layer on the n-type oxide layer.

14. The resistive memory device of claim 13, wherein the n-type oxide layer includes one selected from the group consisting of InZn oxide, InSn oxide, Zn oxide, Sn oxide, Ti oxide, and compounds thereof.

15. The resistive memory device of claim 13, wherein the p-type oxide layer includes one selected from the group consisting of Cu oxide, Ni oxide, CuAl oxide, ZnRh oxide, SrCu oxide, and compounds thereof.

16. The resistive memory device of claim 13, wherein the plasma includes nitrogen.

17. The resistive memory device of claim 13, wherein the at least one first electrode is a plurality of first electrodes arranged in parallel as wires,
the at least one second electrode is a plurality of second electrodes arranged in parallel and crossing the plurality of first electrodes, and
the first stacked structure is at an intersection point of each of the plurality of first and second electrodes.

18. The resistive memory device of claim 13, further comprising:
at least one third electrode under the at least one first electrode and separate from the at least one first electrode; and
a second stacked structure including a second resistance changing layer and a second switching device between the at least one first and third electrodes.

19. The resistive memory device of claim 18, wherein the second switching device includes a diode.

20. The resistive memory device of claim 19, wherein rectifying directions of the first and second switching devices are either the same or opposite from each other.

21. The resistive memory device of claim 18, wherein the first switching device, the first resistance changing layer, and the at least one second electrode are on the at least one first electrode, and
the second switching device, the second resistance changing layer, and the at least one third electrode are under the at least one first electrode.

22. The resistive memory device of claim 18, wherein the at least one first electrode is a plurality of first electrodes arranged in parallel as wires,
the at least one third electrode is a plurality of third electrodes arranged in parallel and crossing the plurality of first electrodes, and
the second stacked structure is at an intersection point of each of the plurality of first and third electrodes.

23. The resistive memory device of claim 22, wherein the resistive memory device includes a multi-crossing memory device having a cell structure of 1 diode (1D)-1 resistor (1R).
